(19) United States
(12) Patent Application Publication
(10) Pub. No.: US 2020/0341525 A1
(43) Pub. Date: Oct. 29, 2020

(54) ELECTRONIC APPARATUS

(71) Applicant: LENOVO (SINGAPORE) PTE. LTD., Singapore (SG)

(72) Inventors: Akinori Uchino, Kanagawa (JP); Takuroh Kamimura, Kanagawa (JP); Ryota Watanabe, Kanagawa (JP); Hiroshi Yamazaki, Kanagawa (JP)

(21) Appl. No.: 16/855,377

(22) Filed: Apr. 22, 2020

(30) Foreign Application Priority Data
Apr. 25, 2019 (JP) 2019-83738

(51) Int. Cl. G06F 1/20; G06F 1/16; H05K 7/14; H05K 7/20

(52) U.S. Cl. CPC G06F 1/203; H05K 7/20509; H05K 7/1417; G06F 1/1679

(57) ABSTRACT

An electronic apparatus is disclosed. The electronic apparatus includes a chassis member, a processor provided inside the chassis member, a prong portion provided on the chassis member, a heat spreader provided inside the chassis member to transport heat generated by the processor, and a hook provided to the heat spreader and to be engaged with the prong portion. The hook includes arms extending in an engagement direction in which the hook is engaged with the prong portion, and an engagement piece connected to the arms and extending in the lateral direction. The prong portion includes a projection projecting in the outward direction to be engaged with the engagement piece. The engagement piece is in line contact or point contact with the projection, as to the engagement direction. The arms are not in contact with the projection as to the lateral direction.

### PRIORITY CLAIM

The present application claims benefit of priority under 35 U.S.C. §§ 120, 365 to the previously filed Japanese Patent Application No. JP2019-83738 with a priority date of Apr. 25, 2019, which is incorporated by reference herein.

### TECHNICAL FIELD

The present invention relates to electronic apparatuses in general, and in particular to an electronic apparatus equipped with a plate-shaped heat transport device.

### BACKGROUND

An electronic apparatus, such as a computer, may include a plate-shaped heat transport device, such as a heat spreader, for transporting heat generated by a heating element, such as a central processing unit (CPU) or the like, in order to prevent excessive increase in temperature of the heating element. The plate-shaped heat transport device is in contact with the heating element at a predetermined point.

The plate-shaped heat transport device having high heat transport capability can sufficiently receive and diffuse the heat from the heating element. However, if the plate-shaped heat transport device is secured to a chassis with a screw, heat is also transferred to the chassis. This is because a screw is made of metal and has a high heat transfer coefficient. As the head portion of a screw has some extent of area, which makes a large contact area with the plate-shaped heat transport device, a significant amount of heat will be transferred to the chassis.

In addition, if the chassis is made of metal, such as magnesium alloy, the temperature can increase to some extent. A user may feel uncomfortable when holding or touching a chassis at an increased temperature.

Consequently, it would be desirable to provide an electronic apparatus capable of suppressing increase in chassis temperature.

### SUMMARY

In accordance with an embodiment of the present disclosure, an electronic apparatus includes a chassis; a heating element provided inside the chassis; a prong portion provided on the chassis; a plate-shaped heat transport device provided inside the chassis to transport heat generated by the heating element; and a hook provided to the plate-shaped heat transport device with the hook being engaged with the prong portion.

The hook may include arms extending in an engagement direction in which the hook is engaged with the prong portion, and an engagement piece connected to the arms and extending in a first direction orthogonal to the engagement direction. The prong portion may include a projection projecting in a second direction orthogonal to the engagement direction and the first direction, the projection being engaged with the engagement piece. The engagement piece may be in line contact or point contact with the projection, as to the engagement direction.

All features and advantages of the present disclosure will become apparent in the following detailed written description.

### BRIEF DESCRIPTION OF THE DRAWINGS

The invention itself, as well as a preferred mode of use, further objects, and advantages thereof, will best be understood by reference to the following detailed description of an illustrative embodiment when read in conjunction with the accompanying drawings, wherein:

FIG. 1 is a perspective view of an electronic apparatus according to an embodiment closed in a stored state;

FIG. 2 is a perspective view of the electronic apparatus from FIG. 1, open in a use state;

FIG. 3 is a plan view of an inside of the electronic apparatus from FIG. 2;

FIG. 4 is an exploded perspective view of a chassis member and components provided inside the chassis member;

FIG. 5 is a perspective view of a securing unit including a prong portion and a hook in a non-engaged state;

FIG. 6 is a perspective view of the securing unit in an engaged state;

FIG. 7 is a cross-sectional side view of the securing unit in an engaged state;

FIG. 8 is a perspective view of a hook having a spike on the top face of an engagement piece;

FIG. 9 is a partially enlarged cross-sectional plan view of the securing unit in an engaged state;

FIG. 10A illustrates a first engagement aspect of the prong portion and the hook;

FIG. 10B illustrates a second engagement aspect of the prong portion and the hook;

and

FIG. 10C illustrates a third engagement aspect of the prong portion and the hook.

### DETAILED DESCRIPTION

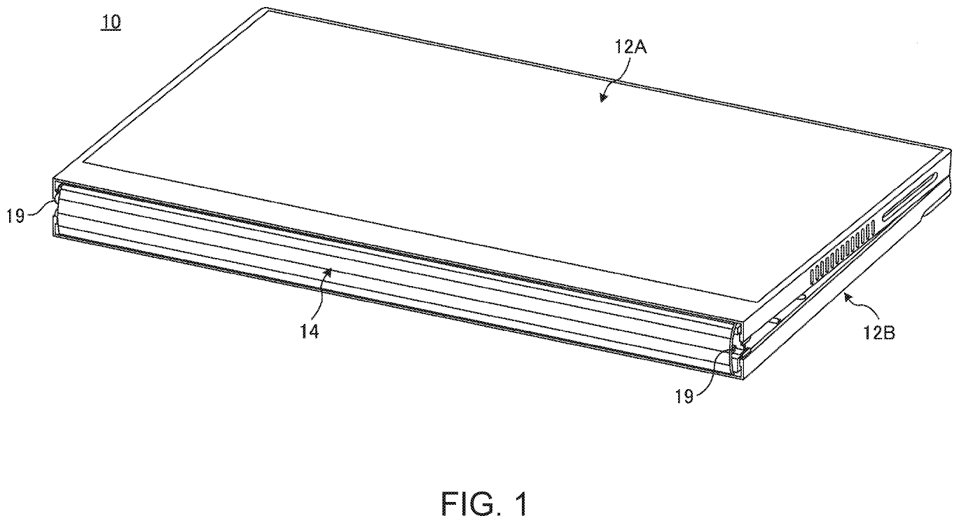

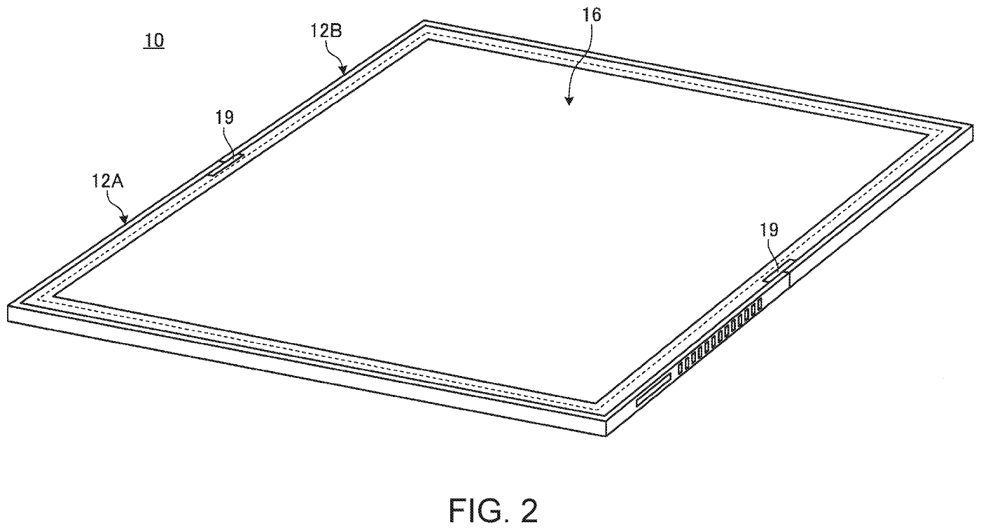

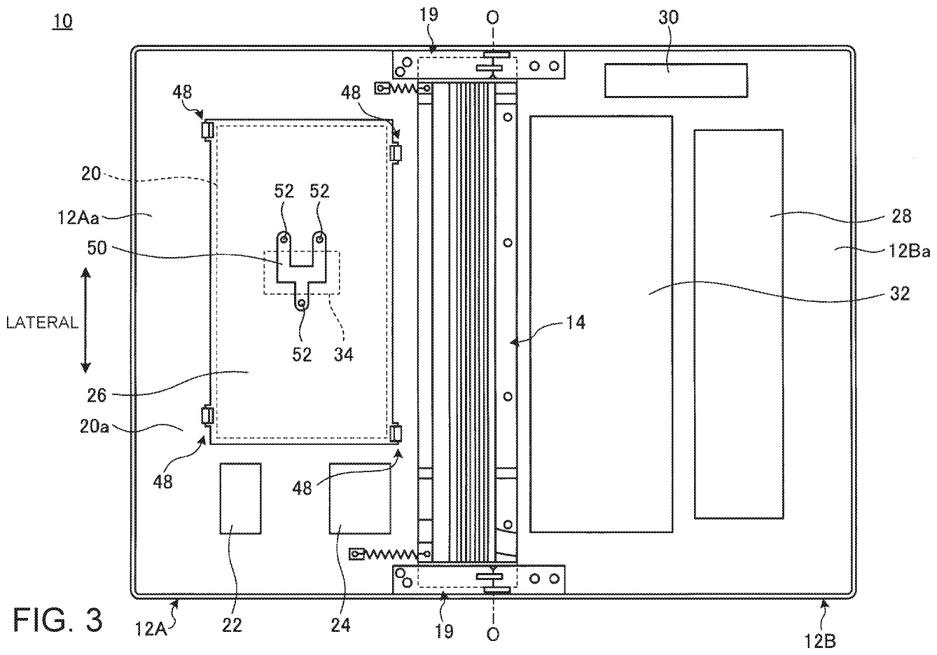

FIG. 1 is a perspective view of an electronic apparatus 10 according to one embodiment, which is closed so as to be in a stored state. FIG. 2 is a schematic perspective view of the electronic apparatus 10 illustrated in FIG. 1, which is open so as to be in a use state. FIG. 3 is a schematic plan view of the inside structure of the electronic apparatus 10 illustrated in FIG. 2.

As illustrated in FIGS. 1 and 2, the electronic apparatus 10 includes a first chassis member 12A, a second chassis member 12B, a spine member 14, and a display 16. In this embodiment, a tablet personal computer (PC) that is foldable like a book is referred to as an example of the electronic apparatus 10. The electronic apparatus 10, however, may be a portable phone, a smart phone, an electronic organizer, or the like.

The display 16 is, for example, a touch-panel liquid crystal display. The display 16 has a structure that can be folded together with the chassis members 12A, 12B when the chassis members 12A, 12B are folded. The display 16 is, for example, an organic electroluminescent (EL) flexible display having a highly flexible paper structure, and to be opened or closed along with the opening or closing motion of the chassis members 12A, 12B.

Each of the chassis members 12A, 12B is a rectangular plate member having side walls standing on its three edges other than an edge corresponding to the spine member 14. Each of the chassis members 12A, 12B is made of a plate of metal, such as stainless, magnesium, or aluminum, or of a fiber reinforced resin plate containing reinforced fiber, such as carbon fiber. On the side of the inner surfaces of the chassis members 12A, 12B, the display 16 is secured via a support plate. The chassis members 12A, 12B are connected to each other via a pair of hinge mechanisms 19, 19. The hinge mechanisms 19 connect the chassis members 12A, 12B in such a manner that allows the chassis members 12A, 12B to be folded or unfolded to be in a stored state, as illustrated in FIG. 1, or in a use state, as illustrated in FIG. 2. The line O drawn with a one-dot chain line in FIG. 3 indicates a folding center O, which makes the center of a folding motion of the chassis members 12A, 12B.

As illustrated in FIG. 3, on the inner surface 12Aa of the first chassis member 12A, a rectangular main substrate 20, a communication module 22, a solid state drive (SSD) 24, or the like, are securely mounted. The main substrate 20 is, for example, a motherboard. The entire surface of the main substrate 20 is covered with a heat spreader (a metal plate) 26. The main substrate 20 and the heat spreader 26 occupy a large area of the inner surface 12Aa of the first chassis member 12A. Meanwhile, on the inner surface 12Ba of the second chassis member 12B, a sub-substrate 28, an antenna 30, a battery device 32, or the like, are securely mounted.

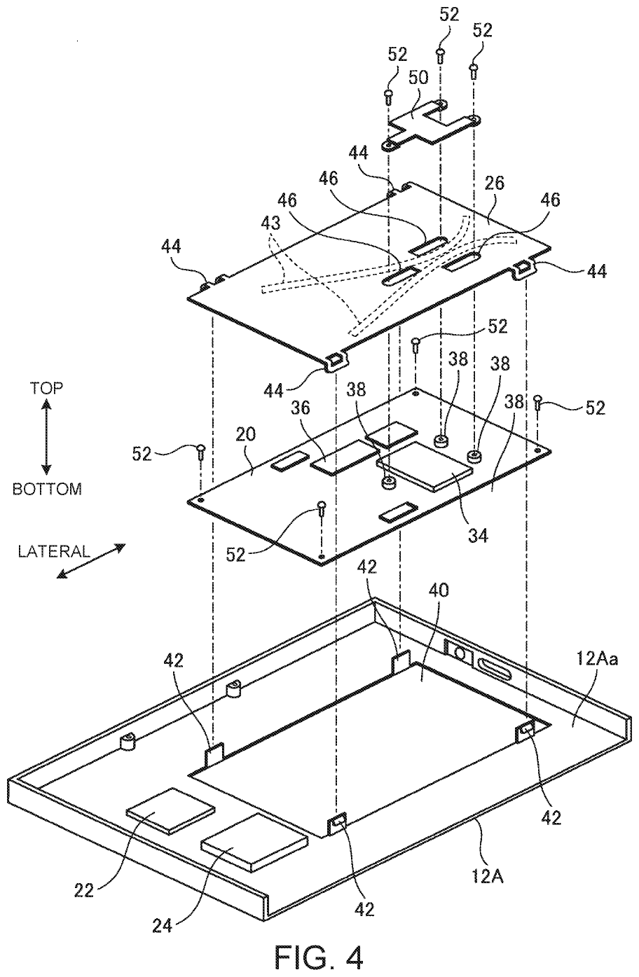

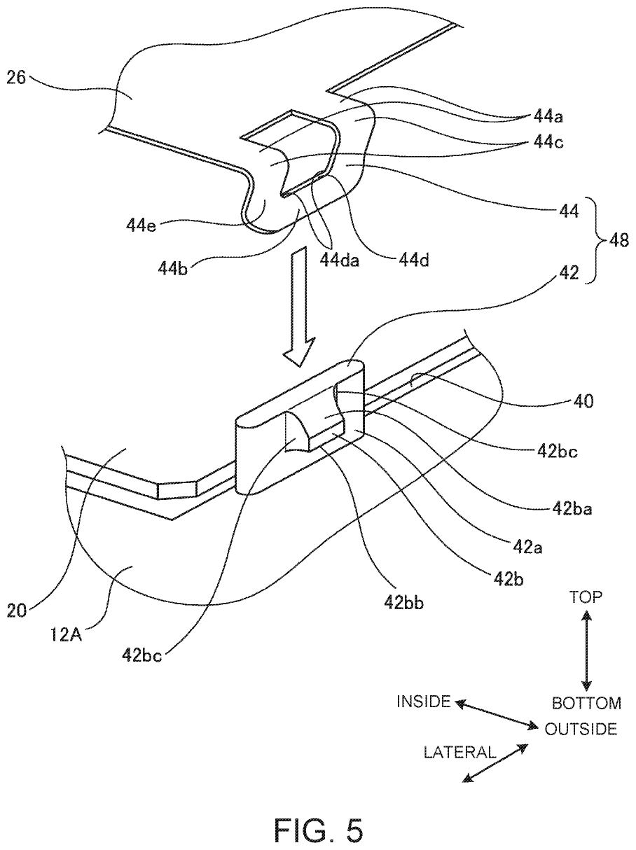

FIG. 4 is an exploded perspective view of the chassis member 12A and components provided in the chassis member 12A. In the description below, a direction perpendicular to the surfaces of the main substrate 20 and the heat spreader 26 is referred to as a top-bottom direction, and the longitudinal direction of the main substrate 20 and the heat spreader 26 is referred to as a lateral direction (a first direction). In the description of a securing unit 48 to be described later (refer to FIG. 5), a side closer to the middle of the main substrate 20 is referred to as an inside, a side closer to the outside of the main substrate 20 is referred to as an outside, and a direction connecting the inside and the outside is referred to an in-out direction (a second direction). The top-bottom direction, the lateral direction, and the in-out direction are orthogonal to one another.

As illustrated in FIG. 4, a central processing unit (CPU) 34, a memory 36, or the like, are mounted on the main substrate 20. The CPU 34 is a heating element that generates the largest heat amount among the electronic components mounted in the chassis members 12A, 12B of the electronic apparatus 10. The CPU 34 is disposed at the substantial middle of the main substrate 20 with three bosses 38 provided therearound. The main substrate 20 is disposed in a shallow rectangular concave 40 formed on the inner surface 12Aa, and secured with a screw 52. Four upstanding prong portions 42 are provided outside the main substrate 20 near the respective corners of the concave 40. Specifically, two prong portions 42 are provided on each of the two longer edges of the concave 40. The prong portion 42 is provided in the first chassis member 12A, where the CPU 34, or a heating element, is provided.

The heat spreader 26 is set so as to have the same shape as, or to be slightly larger than, the main substrate 20 in a plan view. The heat spreader 26 is a plate of metal having high heat transfer characteristics, for example, the metal being copper or an alloy of copper and stainless. Use of an alloy of copper and stainless can produce appropriate mechanical strength. The heat spreader 26 includes two heat pipes 43, four hooks 44 extending downward from its peripheral portion, and three spring slots 46 provided at its substantial middle. The two heat pipes 43 extend so as to define a substantial X shape, while being in contact with the CPU 34, to transport heat to the four corners of the heat spreader 26. The heat spreader 26 has a sufficiently wide area. The heat spreader 26 receives heat from the CPU 34 and diffuses the heat, whereby excessive increase in temperature of the CPU 34 is prevented. A heating element whose heat is to be transported by the heat spreader 26 is not limited to the CPU 34, and any other components in the chassis members 12A, 12B, for example, the SSD 24, the antenna 30, the memory 36, or a battery charger, can be a heating element. A plate-shaped heat transport device that transports heat of a heating element is not limited to the heat spreader 26, and, for example, a paper chamber is usable. The heat spreader 26 is provided in the first chassis member 12A, where the CPU 34, or a heating element, is provided.

The hooks 44 are provided at respective positions corresponding to the prong portions 42. The prong portion 42 and the hook 44 together constitute a securing unit 48 (refer to FIG. 5). Each spring slot 46 is a long slot, and provided at a position corresponding to the boss 38.

On the top surface of the heat spreader 26, a leaf spring 50 is provided. The leaf spring 50 is an elastic thin metal plate, and has arms projecting in three directions. The leading end portion of each arm passes through the spring slot 46 and is secured on the boss 38 with a screw 52. The leaf spring 50 is disposed above the CPU 34 in a plan view. The heat spreader 26 is sandwiched by the leaf spring 50 and the CPU 34 with appropriate pressure, which facilitates heat transfer. The pressure applied by the leaf spring 50 and the CPU 34 sandwiching the heat spreader 26 can be managed through a tightening torque of the screw 52. A heat transfer plate or grease may be provided between the CPU 34 and the heat spreader 26 to enhance the heat transfer characteristics.

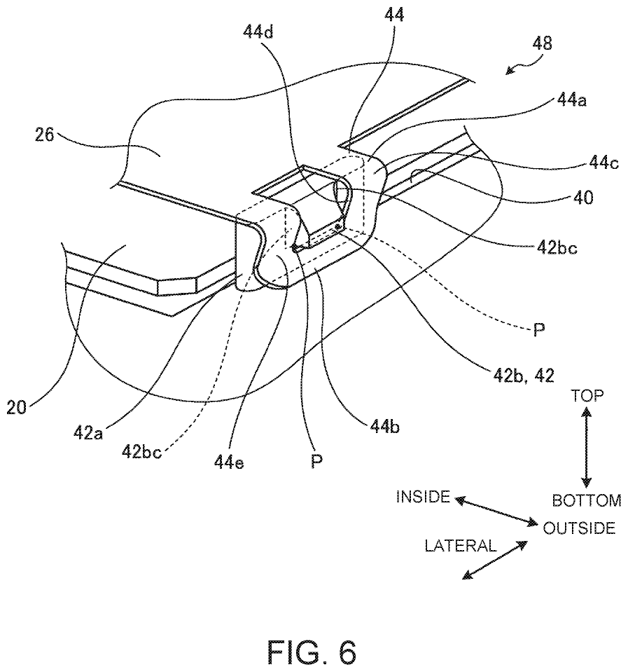

FIG. 5 is a perspective view of the securing unit 48 in a non-engaged state, the securing unit 48 including the prong portion 42 and the hook 44. FIG. 6 is a perspective view of the securing unit 48 in an engaged state. As illustrated in FIG. 5, the prong portion 42 includes a small piece 42a extending along the lateral direction and a projection 42b projecting slightly outward from the side face of the small piece 42a. The projection 42b has a length in the lateral direction that is about a half of that of the small piece 42a, a top face 42ba constituting a smooth curved surface continuing to the top end of the small piece 42a, a bottom face 42bb that is a horizontal surface, and side faces 42bc in the lateral direction constituting smooth curved surfaces continuing to the small piece 42a. The top face 42ba and the side faces 42bc each constitute a curved concave surface. More specifically, the shape of the curved surface of each side face 42bc corresponds to a cylindrical inside circumferential surface whose axis extends in the top-bottom direction, or a surface extending along the top-bottom direction. The side faces 42bc having this shape allow smooth insertion of the hook 44, and, after assembling, can suppress rattling in the lateral and in-out directions. The prong portion 42 is integrally made, for example, with the chassis member 12A, using the same material as that of the chassis member 12A.

The hook 44 includes two arms 44a projecting outward and downward, and an engagement piece 44b extending laterally between the two arms 44a to connect the two arms 44a. Specifically, the arm 44a projects outward from the end of the heat spreader 26 and is bent downward on its upper bent portion 44c so as to extend downward (that is, in the engagement direction). The bending angle of the upper bent portion 44c is 90 or greater. The lower portion of the arm 44a is directed slightly inward. Meanwhile, the engagement piece 44b is bent on its lower bent portion 44e slightly outward relative to the arm 44a. Although the hook 44 is a small bent portion projecting from the heat spreader 26, the hook 44 can have sufficient strength as being made of an alloy of copper and stainless, for example.

On the hook 44, an opening 44d is formed, being enclosed by the two arms 44a and the engagement piece 44b. Each of the end portions 44da on the both lower sides of the opening 44d is shaped like an arc. The length of the hook 44 in the lateral direction is substantially equal to that of the small piece 42a. The hook 44 is formed as a part of the heat spreader 26. The hook 44 is readily formed, for example, by cutting out from a base material integrally with the heat spreader 26 and then bending. The hook 44 has appropriate elasticity.

With this securing unit 48, when the entire heat spreader 26 is lowered as indicated by the outlined arrow indicative of the engagement direction, the engagement piece 44b initially slides relative to the top face 42ba of the projection 42b. The engagement piece 44b and the top face 42ba are both inclined to facilitate the sliding. Then, mainly the upper bent portion 44c is elastically deformed and the engagement piece 44b is accordingly pushed outward.

As illustrated in FIG. 6, as the heat spreader 26 is further lowered, the engagement piece 44b overcomes the projection 42b to be no longer restricted, so that the engagement piece 44b returns inward. Hence, the projection 42b of the prong portion 42 is fit into the opening 44d of the hook 44 and thereby engaged. As described above, the securing unit 48 is of a so-called snap-fit type, and readily engageable, compared with a fastening means such as screwing, and does not require a screw. Alternatively, the securing unit 48 and a screw may be both used depending on a design condition. In using both the securing unit 48 and a screw, securing the heat spreader 26 at a point near a position with the highest temperature with the securing unit 48 can suppress increase in temperature of the chassis member 12A.

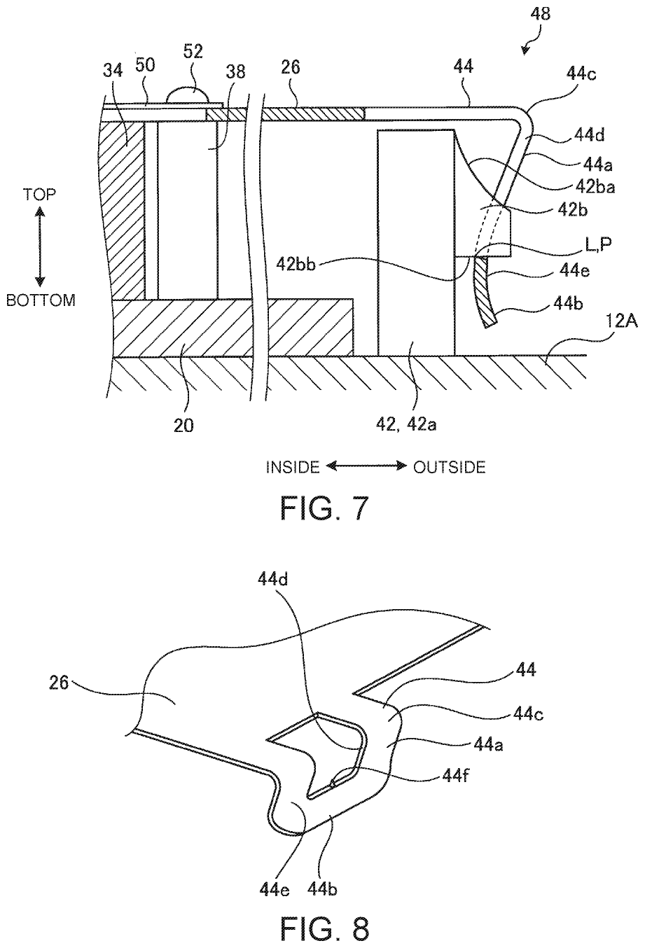

Here, a space is left between the top surface of the main substrate 20 and the bottom surface of the heat spreader 26. This space is positioned at the substantially same level as that of the CPU 34 (refer to FIG. 7). The leaf spring 50 provided (refer to FIG. 4) brings the CPU 34 into close contact with the heat spreader 26. As the engagement piece 44b is directed slightly outward on its lower bent portion 44e, the engagement piece 44b can be readily pulled outward with a finger or a tool, which is preferable in disengaging the securing unit 48.

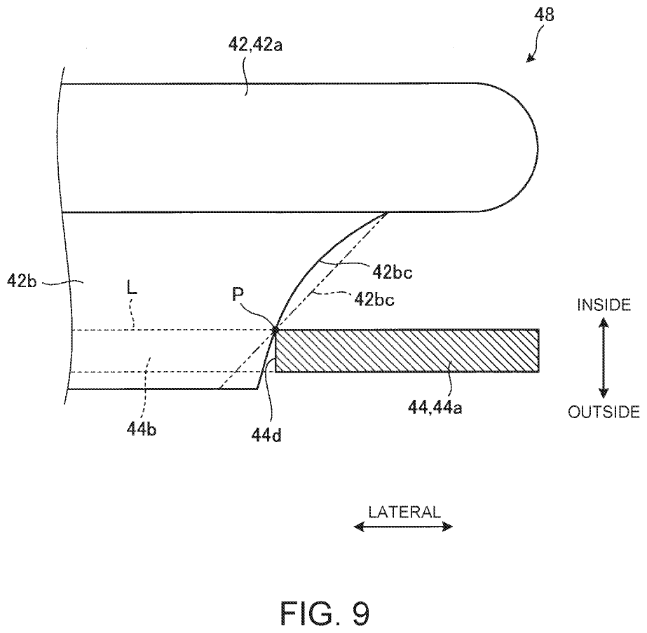

FIG. 7 is a cross-sectional side view of the securing unit 48 in an engaged state. As illustrated in FIG. 7, the top end of the engagement piece 44b is in contact with the bottom face 42bb of the projection 42b whereby the prong portion 42 is engaged with the hook 44. The engagement piece 44b elastically presses the bottom face 42bb with an appropriate pressure. The plate thickness of the hook 44 including the engagement piece 44b is suitably thin, and the engagement piece 44b, inclined on its lower bent portion 44e, is in contact with the bottom face 42bb diagonally such that the contact portion is on a contact line L (refer to FIG. 9) along the lateral direction (a direction perpendicular to the paper surface of FIG. 7), in which the contact area in the engagement direction is sufficiently small. Moreover, the upper portion of the small piece 42a is not in contact with the arm 44a. Thus, no heat is transferred directly from the upper portion.

As illustrated in FIG. 8, a small spike 44f may be provided on the top face of the engagement piece 44b so that the engagement piece 44b is in point contact with the bottom face 42bb of the projection 42b for further reduction in contact area. Note that a line contact and a point contact referred to in this application does not mean a condition in which the width and area are strictly zero mathematically, but, needless to say, means a condition in which a line has a sufficiently narrow width and a point has a sufficiently small area from an engineering point of view. For example, even a manner of contact in which the entire top end face of the engagement piece 44b is in contact with the bottom face 42bb can be referred to as a line contact when the engagement piece 44b is sufficiently thin.

FIG. 9 is a partially enlarged cross-sectional plan view of the securing unit 48 in an engaged state. As illustrated in FIG. 9 and FIG. 6, the arm 44a and the projection 42b are not in contact with each other in the lateral direction. The point P in FIG. 9 and FIG. 6 is an end point of the contact line L, and is an explicit indication of a portion where the side face 42bc of the projection 42b is in contact with the end portion 44da of the opening 44d of the hook 44. The point P is on the bottom end edge of the side face 42bc, and the side face 42bc is not in contact with the hook 44.

That is, whereas the side face 42bc is a curved concave surface along the top-bottom direction, the arm 44a is bent on its upper bent portion 44c so as to be inclined slightly inward and elastically urged inward due to elasticity. Hence, a part of the opening 44d abuts on the bottom end of the side face 42bc in any position at point P. The projection 42b has a shape whose width in the lateral direction becomes narrower as it goes in the projection direction, and the side face 42bc can have, for example, an inclined surface not curved as indicated by a virtual line. Nevertheless, if the side face 42bc is a curved surface, the projecting outer end portion of the projection 42b can have a little longer length in the lateral direction, which can stabilize the engagement.

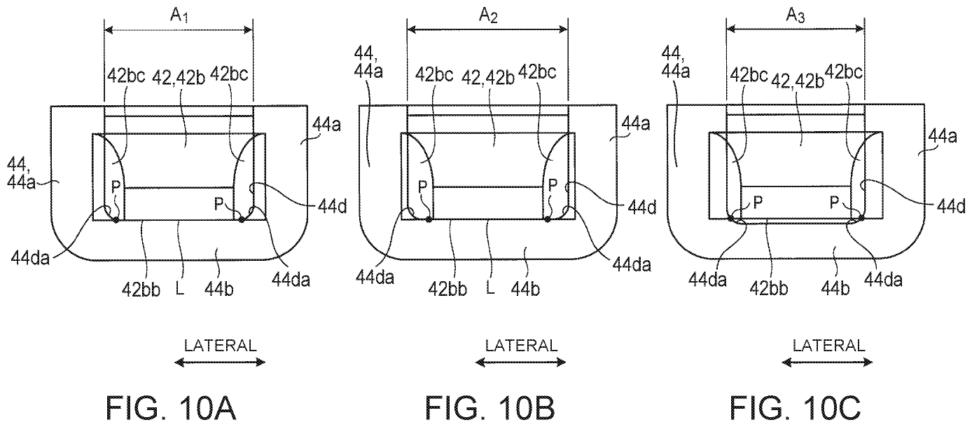

FIGS. 10A-10C illustrate engagement aspects of the prong portion 42 and the hook 44, in which FIG. 10A illustrates a first engagement aspect; FIG. 10B illustrates a second engagement aspect; and FIG. 10C illustrates a third engagement aspect.

As illustrated in FIG. 10A, the length A1 of the opening 44d of the hook 44 in the lateral direction is set to a predetermined length such that the both end points P of the contact line L between the bottom face 42bb of the projection 42b and the engagement piece 44b substantially coincide with the end portions 44da of the opening 44d. With the above, the positions of the prong portion 42 and the hook 44 in the lateral direction are determined.

As illustrated in FIG. 10B, the length A2 of the opening 44d of the hook 44 in the lateral direction is set slightly longer than the length A1 in FIG. 10A such that the both end points P of the contact line L are positioned slightly spaced apart from the respective end portions 44da. This allows some degree of freedom in positioning the prong portion 42 and the hook 44 in the lateral direction, so that some error in dimension can be tolerated.

As illustrated in FIG. 10C, the length A3 of the opening 44d of the hook 44 in the lateral direction is set slightly shorter than the length A1 in FIG. 10A such that no contact line L exists between the bottom face 42bb of the projection 42b and the engagement piece 44b, which is unlike FIG. 10A, and the hook 44 is in contact with the projection 42b only at the points P on the arc portions of the two end portions 44da. That is, the engagement piece 44b is in point contact with the projection 42b at two points P alone. This can reduce the contact area.

As described above, in the electronic apparatus 10, the contact area where the prong portion 42 is in contact with the hook 44 in the securing unit 48 is sufficiently small. In particular, compared with fastening with a screw, as a manner of engagement without a pressing surface, such as a head portion of a screw, is employed for securing, a small contact area is resulted. With the above, heat is unlikely transferred from the heat spreader 26 to the chassis member 12A via the hook 44 and the prong portion 42. This can suppress increase in temperature of the chassis member 12A, and can prevent giving a sense of discomfort to a user touching the chassis member 12A.

As has been described, the present invention provides an improved electronic apparatus capable of suppressing increase in chassis temperature.

While the invention has been particularly shown and described with reference to a preferred embodiment, it will be understood by those skilled in the art that various changes in form and detail may be made therein without departing from the spirit and scope of the invention.

What is claimed is:

1. An electronic apparatus, comprising:
a chassis;
a heating element located within said chassis;
a prong portion provided on the chassis;
a plate-shaped heat transport device located within said chassis, wherein said plate-shaped heat transport device transports heat generated by said heating element; and
a hook provided to said plate-shaped heat transport device, wherein said hook is engaged with said prong portion.

2. The electronic apparatus of claim 1, wherein said hook includes
a plurality of arms extending in an engagement direction in which said hook is engaged with said prong portion; and
an engagement piece connected to said arms and extending in a first direction orthogonal to said engagement direction.

3. The electronic apparatus of claim 2, wherein said prong portion includes a projection projecting in a second direction orthogonal to said engagement direction and said first direction, said projection is engaged with said engagement piece.

4. The electronic apparatus of claim 3, wherein said engagement piece is in line contact with said projection, as to said engagement direction.

5. The electronic apparatus of claim 3, wherein said engagement piece is in point contact with said projection, as to said engagement direction.

6. The electronic apparatus of claim 2, wherein said arms are in non-contact with said projection as to said first direction.

7. The electronic apparatus of claim 1, wherein said heating element is provided on a substrate that is securely screwed to said chassis.

8. The electronic apparatus of claim 7, wherein said prong portion is disposed outside said substrate.

9. The electronic apparatus of claim 1, wherein said prong portion is integrally formed with said chassis.

10. The electronic apparatus of claim 1, wherein said plate-shaped heat transport device is a metal plate.

11. The electronic apparatus of claim 10, wherein said hook includes a bending part of said metal plate.

12. The electronic apparatus of claim 10, wherein said metal plate is made of an alloy of copper and stainless.
